(19) United States
(12) Patent Application Publication
(10) Pub. No.: US 2015/0027802 A1
(43) Pub. Date: Jan. 29, 2015

(54) CASE FOR PORTABLE ELECTRONIC DEVICE AND SOUND CHANNEL

(71) Applicant: Catalyst Medium Four, Inc. (dba CM4, Inc.), Austin, TX (US)

(72) Inventors: Matthew Timothy Altschul, Austin, TX (US); Beejan Soheili, Chula Vista, CA (US)

(73) Assignee: Catalyst Medium Four, Inc. (dba CM4, Inc.), Austin, TX (US)

(21) Appl. No.: 14/339,106

(22) Filed: Jul. 23, 2014

Related U.S. Application Data
(60) Provisional application No. 61/857,679, filed on Jul. 23, 2013.

(51) Int. Cl. H04R 1/02; H05K 5/00

(52) U.S. Cl. CPC H04R 1/02; H05K 5/0086
USPC 181/177

(57) ABSTRACT

Disclosed is a device that in many embodiments may be comprised of what is commonly described as a “case” in the portable electronic device industry, which is largely a cavity which envelopes the portable electronic device. This case may be one solid piece, or be multiple pieces that then assemble around the portable electronic device to protect and/or decorate the device. In one embodiment, the case's functional purpose is serving as a wallet, with a slot to store items such as credit or identification cards. In a preferred embodiment the case component may then be comprised of one or more sound guides which are designed to control and direct sound from its origin and emit the sound towards the front or the face of the case. This origin is typically one or more speakers, and the guides may additionally serve to alter or enhance the acoustics of the produced sound.

This application claims priority from U.S. Provisional Patent Application No. 61/857,679 filed on Jul. 23, 2013, which is hereby incorporated by reference in its entirety.

### TECHNICAL FIELD OF THE INVENTION

The invention relates to electronic devices, mobile devices and portable electronics or mobile device accessories, and more specifically for cases or enclosures for these devices comprising sound transmitting channels for improving the audio performance of the speakers within these devices.

### BACKGROUND OF THE INVENTION

Phone cases and other enclosures often cover the entire electronic device with the exception of the display screen and perhaps the power button depending on its location. This arrangement often leaves the sound speaker completely covered by the case. Some cases may provide an opening at the speaker's location. However, there remains a need for multifunctional cases that enable the capturing and redirecting of sound in order to optimize audio performance when a device is secured within a protective or decorative case.

### SUMMARY OF THE INVENTION

Disclosed is a device that in many embodiments may be comprised of what is commonly described as a “case” in the industry, which is largely a cavity which envelopes the portable electronic device. This case may be one solid piece, or be multiple pieces that then assemble around the portable electronic device to protect and or decorate the device. In one embodiment, the case's functional purpose is serving as a wallet, with a slot to store items such as credit or identification cards. In a preferred embodiment the case component may then be comprised of one or more sound guides, as shown herein, which are designed to control and direct sound from its origin. This origin is typically a speaker, and the guides may additionally serve to alter or enhance the acoustics of the produced sound.

The case component may then consist of one or more sound guides, as shown herein, which are designed to control and direct sound from its origin. This origin is typically a speaker, and the guides may additionally serve to alter or enhance the acoustics of the produced sound. The sound guide physical characteristics may vary in order to adjust its acoustical properties, and therefore the manner in which the sound is amplified and projected. These physical characteristics are in many embodiments defined by the shape of the sound entry point into the sound channel, the shape of the “sound channel”, the shape of the exit point, and the types of materials used or surface coatings applied, among others.

In many embodiments, the device redirects audio toward the user from a portable electronic device which has its speaker assembly located somewhere on the device. The portable electronic device may have one or more speakers as part of the speaker assembly, which is then redirected. This redirection may occur with one large flange that encompasses the entire speaker assembly, as seen herein, or multiple flanges that each redirect the audio for their corresponding speaker.

### BRIEF DESCRIPTION OF THE DRAWINGS

FIG. 1 is a close-up isometric view of a device case, illustrating the operation of a sound channel in a portable electronic device.

FIG. 2 is a side cross-sectional view of a sound channel, and portable electronic device.

FIG. 3 is a cutaway isometric view of a portable electronic device and surrounding case.

FIG. 4 is a close-up view of the exit opening of a sound channel.

FIG. 5 shows a case secured to the mobile device with sound depicted exiting the sound channel exit opening.

FIG. 6 shows a case with a portion cut out to depict the location of the sound channel.

FIG. 7 shows a case fitted to a portable electronic device as in FIG. 3.

FIG. 8 depicts the sound dynamics incorporated into the engineering of a sound channel.

FIG. 9 shows dual scooped sound channels for left and right audio channels.

FIG. 10 illustrates a single large sound guide for one or more speakers at the bottom of a portable electronic device.

FIG. 11 illustrates independent sound guides for two speakers in a portable electronic device.

FIG. 12 illustrates the design of one embodiment of the current invention.

FIG. 13 illustrates the design of one embodiment of the current invention.

### DETAILED DESCRIPTION

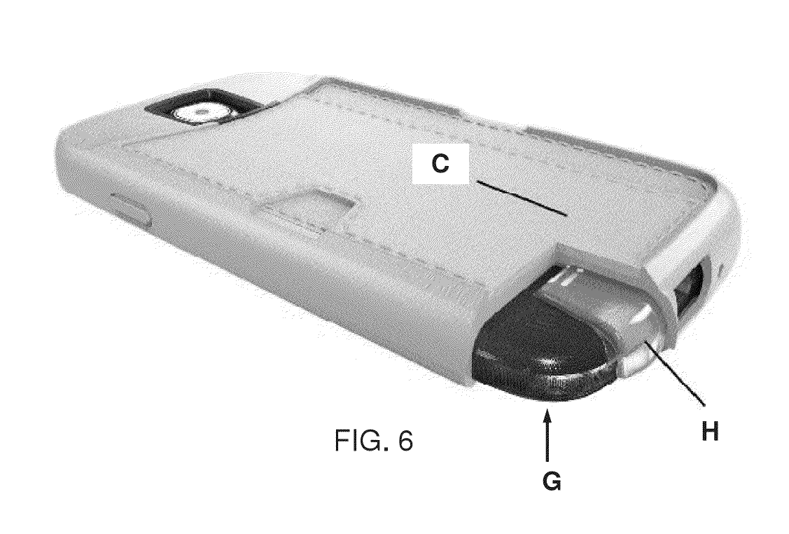

The device may be comprised of what is commonly described as a “case” in the industry, which is largely a cavity that envelopes the portable electronic device. This case may be one solid piece, or be multiple pieces that then assemble around the portable electronic device. The case may serve to protect the device, change the device's appearance, and/or serve some functional purpose. In one embodiment, the case's functional purpose is serving as a wallet, with a slot to store items such as credit or identification cards (see FIG. 6).

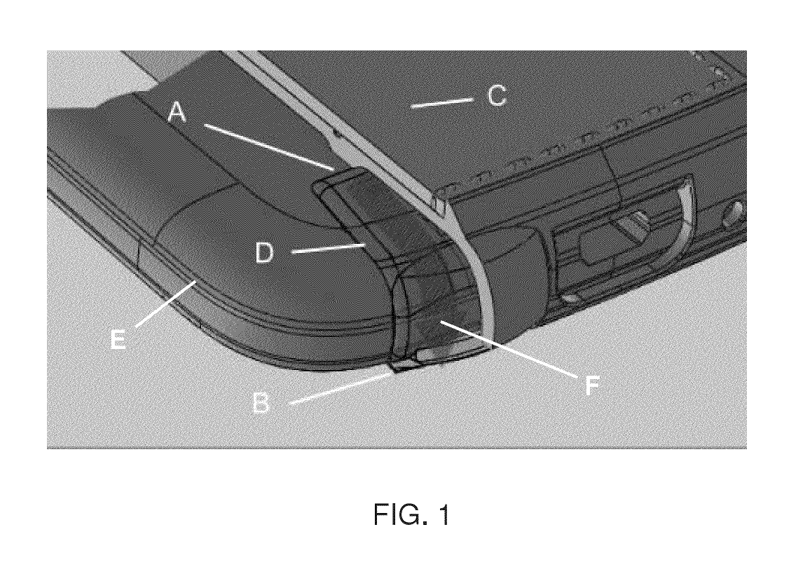

The case may comprise one or more sound guides, as seen in FIGS. 1, 2, 4, 5, 6, and 8, which are designed to control and direct sound from its origin. This origin is typically one or more speakers, and the guides may additionally serve to alter or enhance the acoustics of the produced sound.

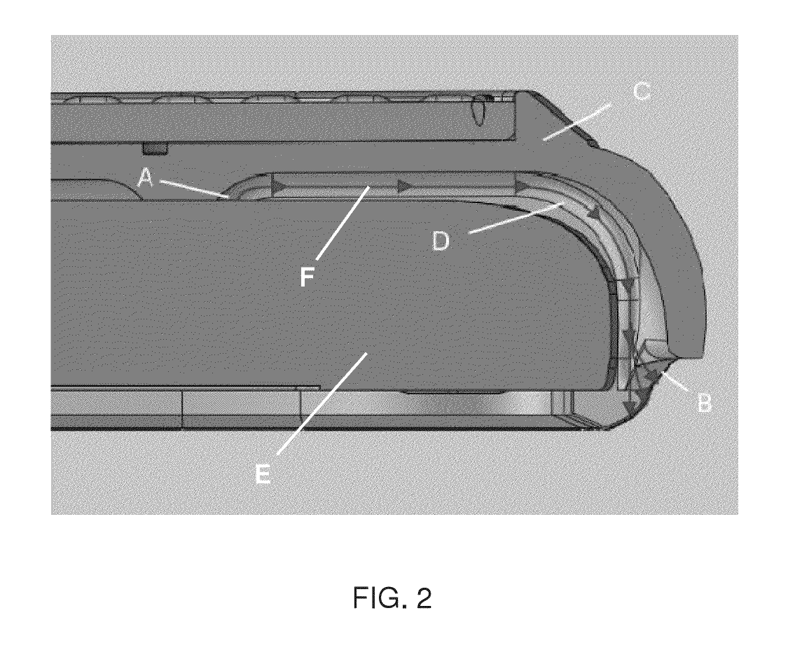

The sound guide physical characteristics may vary in order to adjust its acoustical properties, and therefore the manner in which the sound is transmitted and projected. These physical characteristics are in many embodiments defined by a) the shape of the sound entry point, b) shape of the “sound channel”, c) shape of the exit point, and d) the types of materials used or surface coatings applied, among others. These physical characteristics are illustrated in FIGS. 1, 2, and 8. The individual width, height, and shape of the sound guides may vary in any dimension, and are not limited to the physical dimensions of the portable electronic device. For example, the sound exit point A in FIGS. 1 and 2 could extend beyond the front surface of the portable electronic device. There are numerous types of materials that may be used to form the sound channel and these may be selected for various embodiments based on those materials that reflect sound best, such as those that are rigid, smooth or non-porous. Flexible, rough, and porous materials may also be used in alternative embodiments.

In FIGS. 1 and 2, a basic design element of the case in embodiments of the invention is the location of the speaker adjacent end A of the sound channel A, and the sound exit end B of the sound channel, the route between A and B, and the shape of the sound channel over the route from A to B. The route and shape in certain embodiments is from back to front, in a conical shape that is larger at point B than it is at point A. However, alternative embodiments need not be limited to this paradigm, and the design of A, B, the route taken between A and B, and the general shape of the sound channel between A and B may be any shape, size, or geometrical design. Further embodiments include multiple separate and distinct sound channels wherein each speaker on a device has a sound channel with a point A and opening at point B with a channel between A and B.

Still other embodiments include a single speaker adjacent opening A with a bifurcated sound channel ending in multiple openings B at other locations within the case. Other design schemes include a means for closing or covering a sound channel at either point A or B, or both.

In a preferred embodiment, the case and scoop may be made of a TPU (Thermoplastic PolyUrethane) material. Other appropriate materials include, but are not limited to, any injection mold material or resin such as PC (Polycarbonate) or ABS (Acrylonitrile Butadiene Styrene). The numerous materials that may be employed with the current invention include other metals, plastics, polymers, and rubbers that will be apparent to those skilled in the art.

The sound channel, either as a separate piece or when directly formed within the case material, may contain one or more inserts substantially in the shape of the sound channel for providing different characteristics of sound reflection. Such inserts may be comprised of metal, tin, aluminum, plastics, or other hard smooth surfaced materials. A series of inserts may also be used wherein the insert is approximately in the shape of the sound channel with a smaller diameter, the diameter decreasing with each additional insert to provide a series of sound channels within the main sound channel.

The sound channel in various embodiments may also contain internal surface features such as a rivets, ridges, indentations, or raised areas of any shape or dimensions to affect the sound reflection and the characteristics of the sound emitting from the exit point B.

FIG. 1 is a close-up isometric view of a case C, illustrating a speaker and sound channel in a portable electronic device E. A is the portion of the sound channel adjacent to the speaker of the device. B is the second end of the sound channel, in this case towards the front of the device and case. C is the case, while D is the sound channel piece. The arrow F represents the passage of sound from the speaker of the device, passing through the sound channel and emerging from the sound exit end B of the sound channel.

FIG. 2 is a side cross-sectional view of a sound channel, and portable electronic device E. Callouts A-D correspond to those in FIG. 1. The series of arrows F corresponds to arrow F in FIG. 1 and represents the passage of sound from the device speaker, adjacent to A, through the sound channel D, and then emerging from the second end of the channel at B.

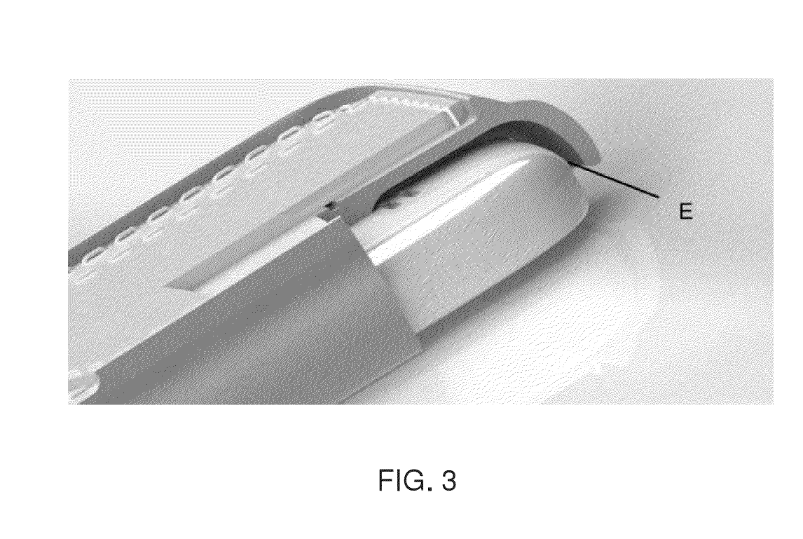

FIG. 3 is a cutaway isometric view of a portable electronic device and surrounding case. E is the empty volume within the case C where the sound channel piece may be accommodated.

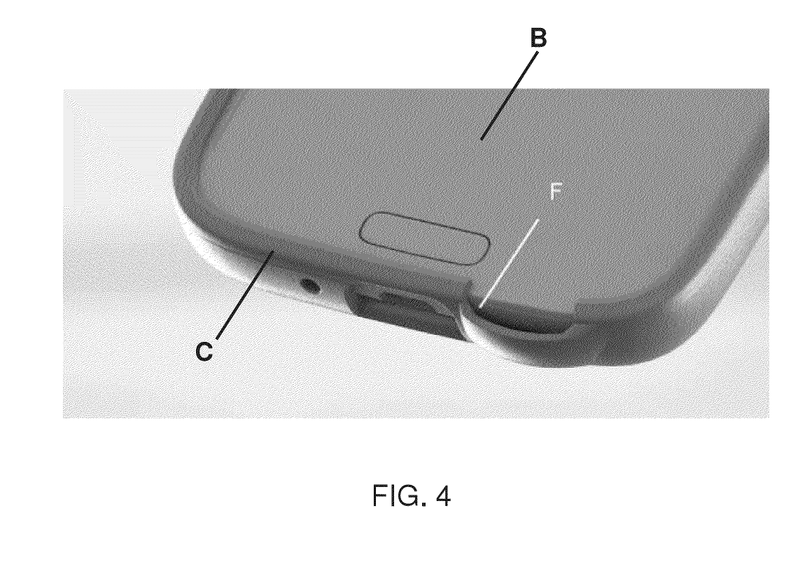

FIG. 4 is a close-up view of the exit point of a sound channel with a sound exit F in case C enclosing portable electronic device B.

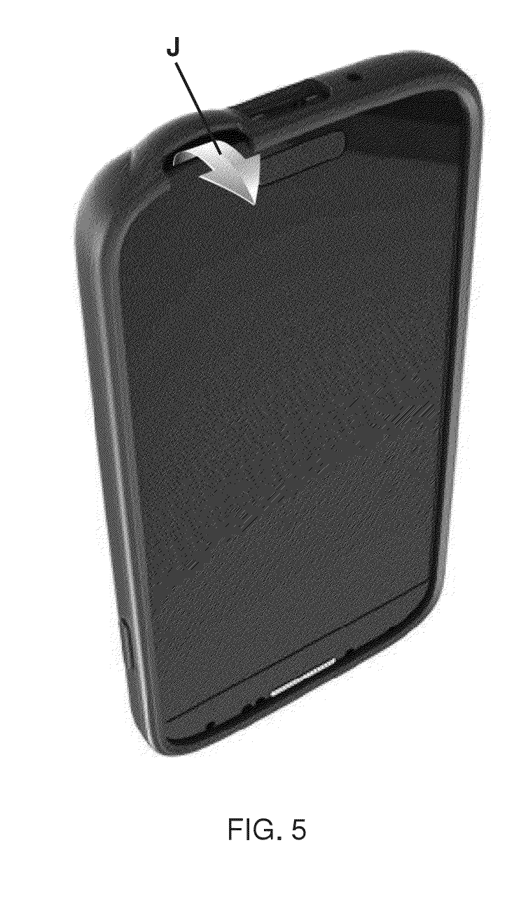

FIG. 5 shows a case secured to the mobile device with sound depicted (arrow J) exiting the sound channel exit point.

FIG. 6 shows a case C with a portion G cut away to depict the location of the sound channel H.

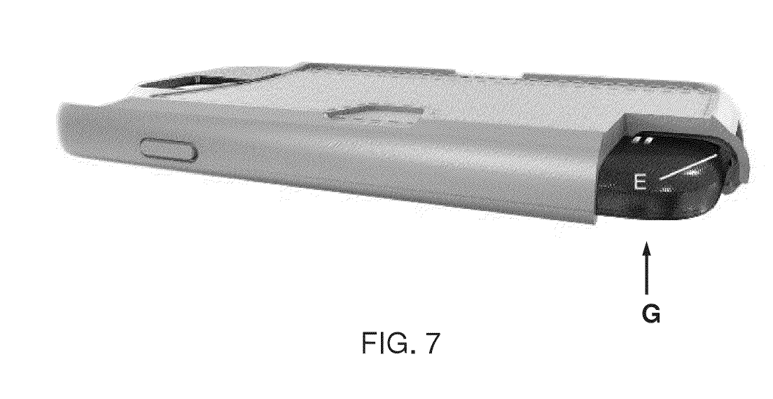

FIG. 7 shows a case fitted to a portable electronic device with a portion G cut away as in FIG. 6. E is the empty volume where the sound channel piece H (see FIG. 6) may be accommodated.

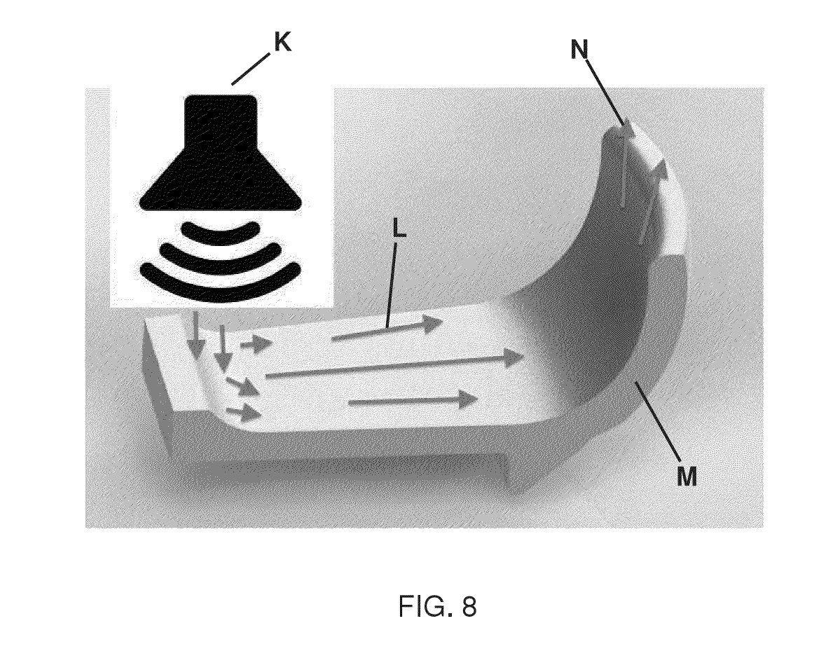

FIG. 8 depicts the sound dynamics incorporated in the engineering of the sound channel M. Sound L from the speaker K in the portable electronic device (not shown) is reflected along a curved surface of the sound channel M to the exit point at N.

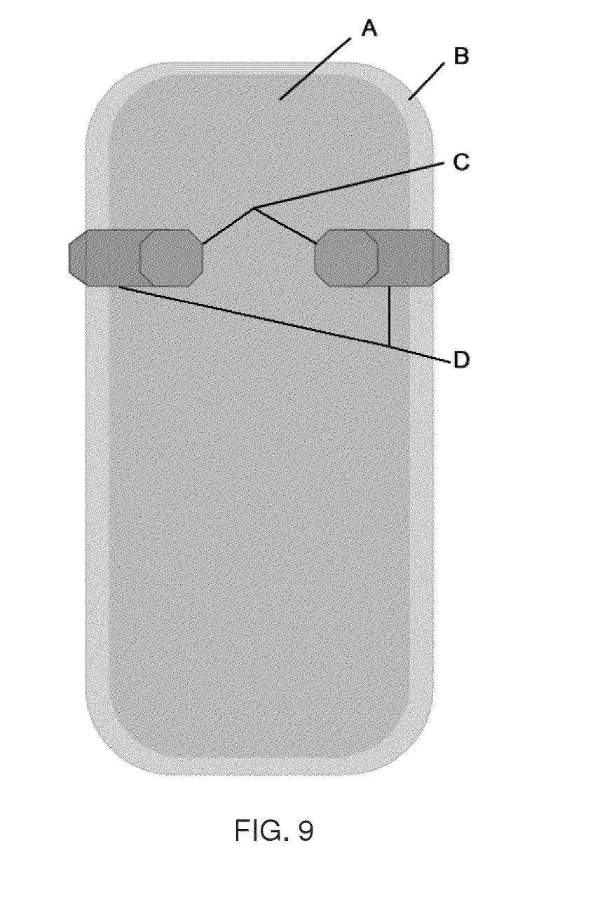

FIG. 9 shows dual scooped sound channels for left and right audio channels. The portable electronic device A is situated within the device case B, which redirects audio from right and left audio channels. There are separate scooped guides D for each of the speakers C. The speakers correspond to right and left audio channels. The use of separate guides D for each speaker results in focused redirection for each particular audio channel. The sound is redirected as with the single-guide embodiments shown in FIGS. 1, 2, and 8, but results in an enhanced stereo effect since each channel is individually redirected. The guides are of identical structure, shape, and acoustical properties, so as to produce a symmetrical, balanced stereo effect.

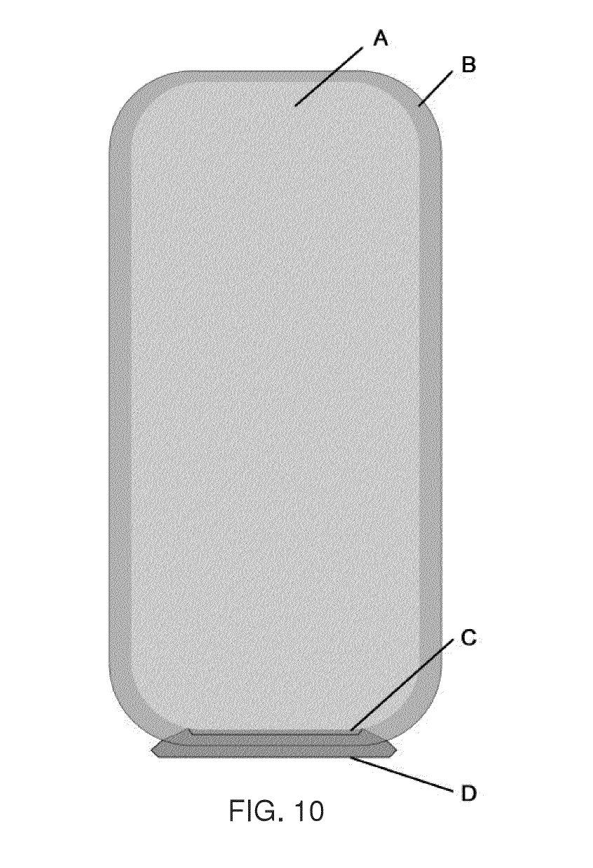

FIG. 10 illustrates a single large sound guide for one or speakers at the bottom of the portable electronic device. The case B redirects audio toward the user from portable electronic device A which has speaker assembly C located along its bottom. The portable electronic device may have one or more speakers as part of the speaker assembly, which is then redirected. This sound redirection occurs with one large guide D that encompasses the entire speaker assembly C.

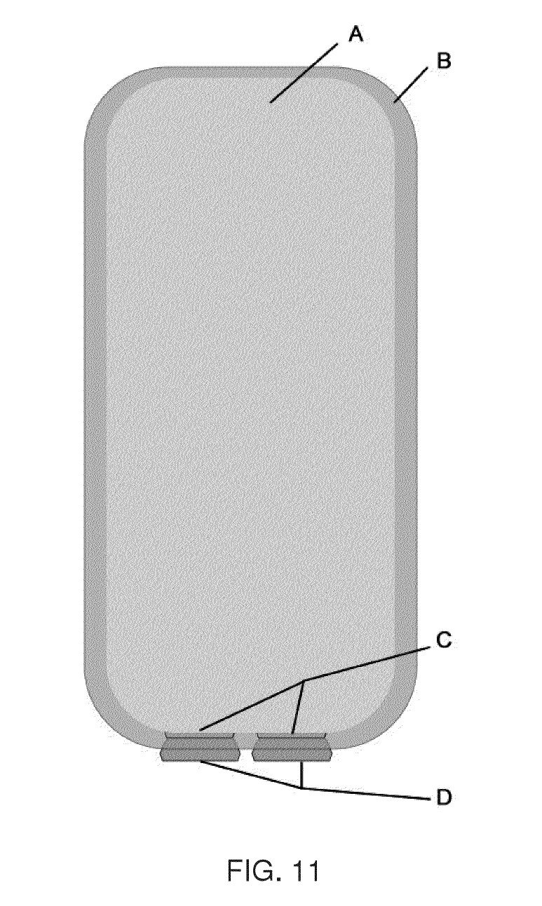

FIG. 11 illustrates independent sound guides for two speakers in a portable electronic device. The speaker assembly C of portable electronic device A comprises two speakers. The audio produced from each of the speakers is redirected through independent sound guides D located within case B, which direct the sound toward the user.

In another embodiment the case and sound channel are a single piece of material, wherein the sound channel comprises an empty volume within the case material.

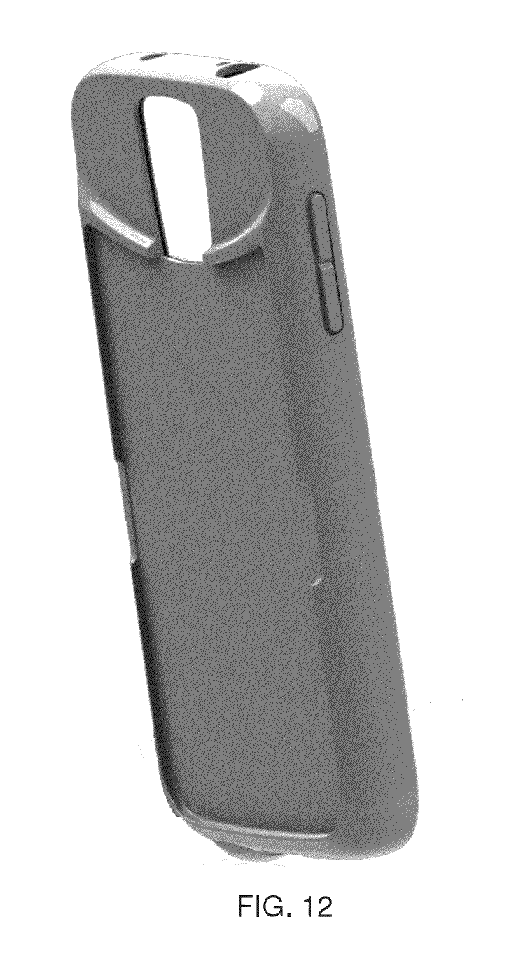

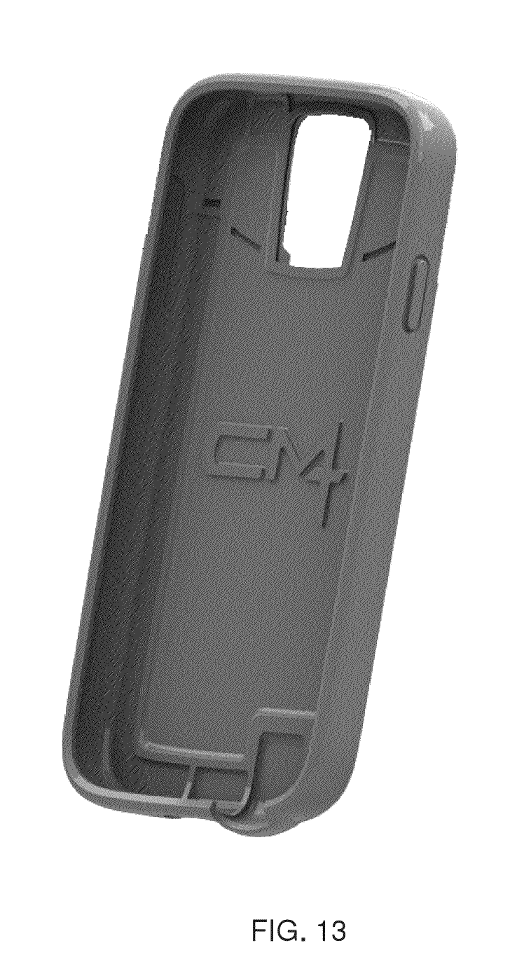

FIGS. 12-13 illustrate the designs of various embodiments of the current invention.

In the foregoing description, the phrase “in one embodiment” is used repeatedly. This phrase generally does not refer to the same embodiment; however, it may. The terms “comprising,” “having” and “including” are synonymous, unless the context dictates otherwise. The following illustrations of various embodiments use particular terms by way of example to describe the various embodiments, but this should be construed to encompass and provide for terms such as “method” and “routine” and the like.

Various aspects of the illustrative embodiments will be described using terms commonly employed by those skilled in the art to convey the substance of their work to others skilled in the art. However, it will be apparent to those skilled in the art that the embodiments described herein may be practiced with only some of the described aspects. For purposes of explanation, specific numbers, materials and configurations are set forth in order to provide a thorough understanding of the illustrative embodiments. However, it will be apparent to one skilled in the art that the embodiments described herein may be practiced without the specific details. In other instances, well-known features are omitted or simplified in order not to obscure the illustrative embodiments.

The characteristics and utilities of the present invention described in this summary and the detailed description below are not all inclusive. Many additional features and advantages will be apparent to one of ordinary skill in the art given the following description. There has thus been outlined, rather broadly, the more important features of the invention in order that the detailed description thereof that follows may be better understood, and in order that the present contribution to the art may be better appreciated.

In this respect, by explaining at least one embodiment of the invention in detail, it is to be understood that the invention is not limited in its application to the details of construction and to the arrangements of the components set forth in the description. The invention is capable of other embodiments and of being practiced and carried out in various ways. Also, it is to be understood that the phraseology and terminology employed herein are for the purpose of description and should not be regarded as limiting.

As such, those skilled in the art will appreciate that the conception, upon which this disclosure is based, may readily be utilized as a basis for the designing of other structures, methods and systems for carrying out the several purposes of the present invention. It is important, therefore, that the description be regarded as including such equivalent constructions insofar as they do not depart from the spirit and scope of the present invention.

Further, the purpose of the foregoing abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The abstract is neither intended to define the invention of the application, nor is it intended to be limiting as to the scope of the invention in any way. The characteristics and utilities of the present invention described in this summary and the detailed description below are not all inclusive. Many additional features and advantages will be apparent to one of ordinary skill in the art given the detailed description.

What is claimed is:

1. A device case comprising a cavity fitted to a portable electronic device comprising at least one sound channel either as an empty volume within the device case or as a modular assembly permanently secured to the device case.

2. The device case of claim 1, wherein a first end of the at least one sound channel is in proximity to a sound speaker of the portable electronic device, and a second end of the at least one sound channel opens at a second location.

3. The device case of claim 2, wherein the second location is towards the front or on the face of the device case.

4. The device case of claim 1, wherein the width of the at least one sound channel at the second end is larger than the width at the first end.

5. The device case of claim 1, wherein the at least one sound channel comprises sound reflective material.

6. The device case of claim 5, wherein the sound reflective material comprises rigid, smooth, or non-porous type material.

7. The device case of claim 1, wherein a first end of the at least one sound channel is in proximity to a sound speaker of the portable electronic device, and the at least one sound channel bifurcates into a multiplicity of second ends opening at a multiplicity of second locations.

8. The device case of claim 1, wherein two or more sound channels of approximately identical structure, shape, and acoustical properties carry sound from right and left device speakers to correlating sides on the front of the device, so as to produce a symmetrical, balanced stereo effect.

9. A method of improving sound performance on a portable electronic device secured to a case comprising a speaker, comprising the steps of:
configuring a device case:
to enclose a portable electronic device; and
to comprise at least one sound channel, configured with a first end in proximity to the speaker;
collecting the sound into the first end of the at least one sound channel;
transmitting the sound along the length of the at least one sound channel to a second end; and
emitting the sound from the second end of the at least one sound channel in a direction generally towards the front or from the face of the device case.

10. The method of claim 9 wherein the width of the at least one sound channel at the second end is larger than the width at the first end.

11. The method of claim 9, wherein the at least one sound channel comprises sound reflective material.

12. The method of claim 11, wherein the sound reflective material comprises rigid, smooth, or non-porous type material.

13. The method of claim 9, wherein two or more sound channels of the at least one sound channel approximately identical structure, shape, and acoustical properties carry sound from right and left device speakers to correlating sides on the front of the device, thereby producing a symmetrical, balanced stereo effect.

14. The case as substantially described or depicted herein.

15. The sound channel as substantially described or depicted herein.
